(19) United States
(12) Patent Application Publication
(10) Pub. No.: US 2026/0278764 A1
(43) Pub. Date: Sep. 17, 2026

(54) INSPECTION SYSTEM, INSPECTION METHOD, AND STORAGE MEDIUM

(71) Applicant: Tokyo Electron Limited, Tokyo (JP)

(72) Inventors: Junnosuke MAKI, Koshi City (JP); Nobuyuki SATA, Koshi City (JP); Masato HAYASHI, Koshi City (JP)

(21) Appl. No.: 19/563,224

(22) Filed: Mar. 11, 2026

(30) Foreign Application Priority Data
Mar. 12, 2025 (JP) 2025-039600

(51) Int. Cl. G06T 7/00; G01B 11/14; G01N 21/88; G01N 21/95; G06T 7/73; H04N 23/695

(52) U.S. Cl. CPC G06T 7/0004; G01B 11/14; G01N 21/8851; G01N 21/9501; G06T 7/73; H04N 23/695; G06T 2207/30148; G06T 2207/30204

(57) ABSTRACT

An inspection system for inspecting a substrate processing apparatus including a holder configured to hold a substrate, and a peripheral processor, which has a facing surface facing a peripheral portion of a front surface of the substrate and performs a process on the peripheral portion, includes: an inspection substrate including a support plate held by the holder in place of the substrate, and an capturer provided on the support plate to capture images of the support plate; a storage configured to store a positional relationship between the facing surface and an imaging target provided on the peripheral processor; an acquirer configured to acquire an image including the imaging target from the capturer; and a position detector configured to detect a position of the facing surface based on a position of the imaging target in the image and the positional relationship.

### CROSS-REFERENCE TO RELATED APPLICATION

This application is based upon and claims the benefit of priority from Japanese Patent Application No. 2025-039600, filed on Mar. 12, 2025, the entire contents of which are incorporated herein by reference.

### TECHNICAL FIELD

The present disclosure relates to an inspection system, an inspection method, and a storage medium.

### BACKGROUND

Patent Document 1 discloses a substrate processing apparatus that performs a peripheral exposure process of exposing a peripheral portion of a substrate. Further, Patent Document 1 discloses that the peripheral exposure process is executed after a transfer portion holding the substrate moves to an alignment position.

### PRIOR ART DOCUMENT

### Patent Document

Patent Document 1: Japanese Laid-open Patent Publication No. 2012-222086

### SUMMARY

According to one embodiment of the present disclosure, an inspection system for inspecting a substrate processing apparatus including a holder configured to hold a substrate, and a peripheral processor, which has a facing surface facing a peripheral portion of a front surface of the substrate held by the holder and performs a process on the peripheral portion, includes: an inspection substrate including a support plate held by the holder in place of the substrate, and a capturer provided on the support plate to capture images of surroundings of the support plate; a storage configured to store a positional relationship between the facing surface and an imaging target provided on the peripheral processor such that the imaging target falls within a field of view of the capturer; an acquirer configured to acquire an image including the imaging target from the capturer; and a position detector configured to detect a position of the facing surface based on a position of the imaging target in the image and the positional relationship.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view schematically illustrating an exemplary outline of a configuration of a wafer processing system.

FIG. 2 is a front view schematically illustrating the exemplary outline of the configuration of the wafer processing system.

FIG. 3 is a schematic diagram illustrating an example of a peripheral processing apparatus.

FIG. 4 is a schematic diagram illustrating an example of an inspection system.

FIG. 5 is a schematic diagram illustrating an example of an imaging target provided on a mask.

FIG. 6 is a schematic diagram for explaining a method of detecting inclination.

FIG. 7 is a schematic diagram for explaining an image captured by a capturer.

FIG. 8 is a schematic diagram for explaining a method of detecting a position of a facing surface.

FIG. 9 is a schematic diagram illustrating an example of an inspection system according to a modification.

FIG. 10 is a diagram illustrating an example of a hardware configuration of a control device.

FIG. 11 is a flowchart illustrating an exemplary procedure of detecting a position of a facing surface.

FIG. 12 is a flowchart illustrating the exemplary procedure of detecting a position of the facing surface.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, a wafer processing system as a substrate processing apparatus according to the present embodiment will be described with reference to the drawings. In addition, in the present specification, components having substantially same functional configuration are denoted by same reference numerals, and redundant description thereof is omitted. Some of the drawings illustrate an orthogonal coordinate system defined by an X-axis, a Y-axis, and a Z-axis. In the following embodiment, the Z-axis corresponds to a vertical direction, and the X-axis and Y-axis correspond to a horizontal direction.

### [Wafer Processing System]

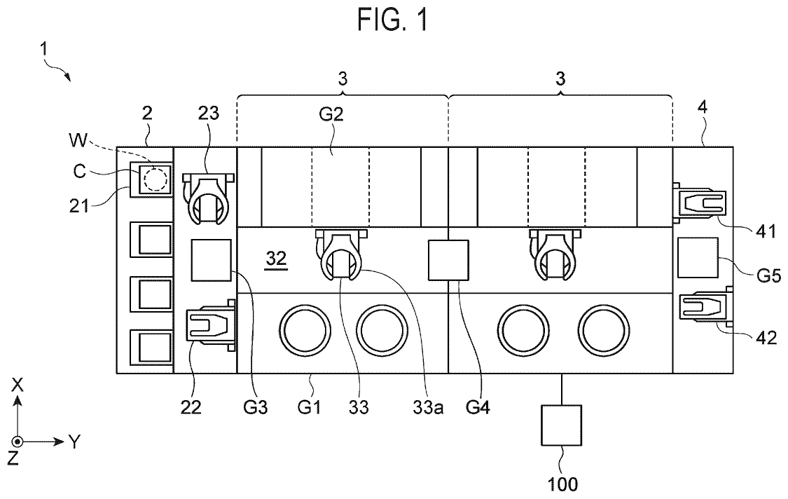

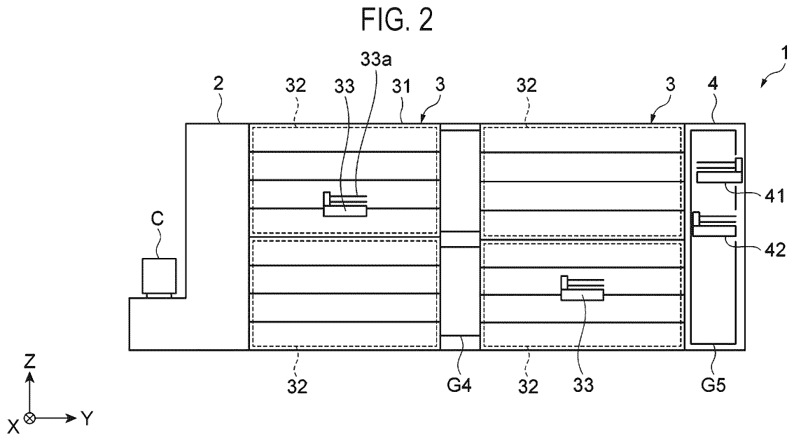

First, a configuration of a wafer processing system according to a present embodiment will be described. FIGS. 1 and 2 are a plan view and a front view, respectively, schematically illustrating an outline of a configuration of a wafer processing system 1 (a substrate processing apparatus). In the present embodiment, a case in which the wafer processing system 1 is a photolithography processing system that performs a resist film formation process and a development process on a wafer W (substrate) will be described as an example.

As illustrated in FIG. 1, the wafer processing system 1 includes a cassette station 2 into and from which a cassette C accommodating a plurality of wafers W is loaded and unloaded, and a processing station 3 including a plurality of various processing apparatuses that perform a predetermined process on the wafer W. Further, the wafer processing system 1 has a configuration in which the cassette station 2, the processing station 3, and an interface station 4, which delivers the wafer W between the processing station 3 and an exposure apparatus (not shown) adjacent to a side opposite to the processing station 3, are integrally connected. In addition, although two processing stations 3 are installed between the cassette station 2 and the interface station 4 as illustrated in FIG. 1, one processing station 3 may be installed, or three or more processing stations 3 may be installed.

In the cassette station 2, a plurality of cassette stages 21 and wafer transfer devices 22 and 23 are provided. The cassette station 2 transfers wafers W between the cassette C placed on the cassette stage 21 and the processing station 3 by means of the wafer transfer device 22 or 23. For this purpose, each of the wafer transfer devices 22 and 23 is provided, as necessary, with a drive mechanism having movement paths in horizontal directions (an X-direction and a Y-direction), a vertical direction (a Z-direction), and a rotational direction around a vertical axis (a θ-direction), and may be provided with a drive mechanism having movement paths in all directions.

At least one of the wafer transfer devices 22 or 23 is capable of delivering the wafers W to and from the cassette C, and is also capable of delivering the wafers W to and from the processing station 3. In addition, the operation of delivering the wafers W to and from the processing station 3 refers to, for example, delivering the wafers W between the processing station 3 and a third block G3 provided with a delivery device that can be accessed by a wafer transfer device 33 in the processing station 3, which will be described later. The third block G3 may be provided with a plurality of delivery devices (not shown) arranged in the vertical direction.

In addition, an inspection apparatus (not shown) for inspecting the wafers W may be provided at a position accessible by either the wafer transfer device 22 or 23.

The processing station 3 is provided with a plurality of blocks, for example, three blocks including a first block G1, a second block G2, and a fourth block G4. Further, as illustrated in FIG. 2, a plurality of layers 31 each including the first block G1 and the second block G2 are stacked in the vertical direction. For example, the first block G1 is provided on a front side of the processing station 3 (a negative X-direction side in FIG. 1), and the second block G2 is provided on a rear side of the processing station 3 (a positive X-direction side in FIG. 1). The fourth block G4 is provided on a side of the interface station 4 (a positive Y-direction side in FIG. 1) of the processing station 3 or at a connection portion with another processing station 3 adjacent thereto. The fourth block G4 may include a plurality of delivery devices arranged in the vertical direction. Further, the above-described third block G3 may be provided in the processing station 3.

In the first block G1, a plurality of processing apparatuses, for example, a film forming apparatus for patterning and a development processing apparatus (neither of which is illustrated), are arranged. The patterning film forming apparatus may include, for example, an antireflection film forming apparatus, besides a resist film forming apparatus. For example, the plurality of processing apparatuses are arranged in the horizontal direction. Further, the number, arrangement, and types of these processing apparatuses can be arbitrarily selected.

In these patterning film forming apparatus and development processing apparatus, for example, a predetermined processing liquid or a predetermined gas is supplied onto the wafer W. As described above, in the patterning film forming apparatus, a formation of a resist film used as a mask for forming a pattern of an underlying film, a formation of an antireflection film for efficiently performing a light irradiation process, such as an exposure process, or the like are performed. On the other hand, in the development processing apparatus, a portion of an exposed resist film is removed to form a concave-convex shape serving as the mask.

For example, in the second block G2, thermal processing apparatuses (not shown) that perform a thermal process such as heating and cooling of the wafers W are arranged in both the vertical and horizontal directions. In addition, although not illustrated, the second block G2 is provided with hydrophobization processing apparatuses that perform a hydrophobization process to improve adhesion between a resist liquid and the wafer W, and peripheral exposure apparatuses that expose a peripheral portion of the wafer W, which are arranged in both the vertical direction (a Z-direction in FIG. 2) and the horizontal direction. The number and arrangement of these thermal processing apparatuses, hydrophobization processing apparatuses, and peripheral exposure apparatuses can also be arbitrarily selected.

As illustrated in FIG. 1, a wafer transfer region 32 is formed in a region sandwiched between the first block G1 and the second block G2 in a plan view. For example, the wafer transfer device 33 is disposed in the wafer transfer region 32.

The wafer transfer device 33 includes, for example, a transfer arm 33a which is movable in the Y-direction, a front-rear direction, the θ-direction, and the vertical direction. The wafer transfer device 33 can move inside the wafer transfer region 32 and transfer the wafer W to a predetermined apparatus in the surrounding first block G1, second block G2, third block G3, and fourth block G4. When a plurality of processing stations 3 are provided as illustrated in FIG. 1, the wafer transfer device 33, which is provided in the processing station 3 located on the interface station 4 side, can transfer the wafer W not only to an apparatus in the first, second, and fourth blocks G1, G2, and G4, but also to a predetermined apparatus in a fifth block G5 to be described later.

For example, as illustrated in FIG. 2, a plurality of wafer transfer devices 33 are arranged in the vertical direction. One wafer transfer device 33 may transfer the wafer W to a predetermined apparatus located at heights corresponding to the upper layers 31 among the plurality of layers 31 which are vertically stacked. For a predetermined apparatus located at heights corresponding to the layers 31 positioned below the upper layers 31, another wafer transfer device 33 may transfer the wafer W. A plurality of wafer transfer regions 32 are provided so as to enable such transfer of the wafers W. In addition, the number of wafer transfer devices 33 and the number of layers 31 corresponding to one wafer transfer device 33, such as providing one wafer transfer device 33 for each layer 31, may be arbitrarily selected.

In addition, a shuttle transfer device (not shown) may be provided in the wafer transfer region 32 or in the first block G1 or the second block G2. The shuttle transfer device linearly transfers the wafer W between a space adjacent to one side of the processing station 3 and another space adjacent to an opposite side of the processing station 3.

The interface station 4 is provided with the fifth block G5 including a plurality of delivery devices, and wafer transfer devices 41 and 42. The interface station 4 transfers the wafer W between the fifth block G5, in which the wafer W is delivered by the wafer transfer device 33, and an exposure apparatus, by using the wafer transfer device 41 or 42. For this purpose, each of the wafer transfer devices 41 and 42 is provided, as necessary, with a drive mechanism having movement paths in the horizontal directions (the X-direction and the Y-direction), the vertical direction (the Z-direction), and the rotational direction around the vertical axis (the θ-direction), and may be provided with a drive mechanism having movement paths in all directions. At least one of the wafer transfer devices 41 or 42 can support the wafer W and transfer the wafer W between the delivery devices in the fifth block G5 and the exposure apparatus.

A cleaning apparatus for cleaning a surface of the wafer W or the above-described peripheral exposure apparatus may be provided in the interface station 4 at positions accessible by either of the wafer transfer device 41 or 42.

The inspection apparatus may be provided in the cassette station 2 as described above, but may alternatively be provided in either the processing station 3 or the interface station 4 at positions accessible by one of the transfer devices (33, 41, or 42 in FIG. 1 or FIG. 2) provided in the processing station 3 or the interface station 4.

The wafer processing system 1 described above is provided with a control device 100. The control device 100 is, for example, a computer and includes a program storage (not shown). The program storage stores a program for controlling a process of the wafer W in the wafer processing system 1. Further, the program storage stores a program for controlling an operation of a drive system of the above-described various processing apparatuses and transfer apparatuses to implement a wafer process in the wafer processing system 1. In addition, the program may be recorded on a non-transitory computer-readable storage medium H and installed in the control device 100 from the storage medium H. Although the storage medium H may include a ROM, a RAM, or a hard disk, its structure and type are not limited and it may be either transitory or non-transitory. In addition, the control device 100 may include portions that store, read, and execute a program for implementing the wafer process and performs communications related to the control device 100, and these portions may be disposed either inside or outside the wafer processing system 1. The control device 100 may include one or more circuits, and may be provided in an integrated manner or a partially separated manner.

### [Operation of Wafer Processing System]

The wafer processing system 1 is configured as described above. Next, an example of a wafer process performed by using the wafer processing system 1 configured as described above will be described.

First, the cassette C accommodating a plurality of wafers W is loaded into the cassette station 2 of the wafer processing system 1 and placed on the cassette stage 21. Thereafter, each wafer W in the cassette C is sequentially taken out by the wafer transfer device 22 or 23 and transferred to the delivery device of the third block G3.

The wafer W transferred to the delivery device of the third block G3 is supported by the wafer transfer device 33 and transferred to the hydrophobization processing apparatus provided in the second block G2. Then, a hydrophobization process is performed. Subsequently, the wafer W is transferred by the wafer transfer device 33 to the resist film forming apparatus and a resist film is formed on the wafer W. Then, the wafer W is transferred to the thermal processing apparatus for a prebake process, and thereafter transferred to the delivery device of the fifth block G5. In addition, when a plurality of processing stations 3 are provided as illustrated in FIGS. 1 and 2, the wafer W is first placed on the delivery device of the fourth block G4 before being transferred to the delivery device of the fifth block G5, and is delivered between a plurality of wafer transfer devices 33. Further, the wafer W may be transferred by the wafer transfer device 33 to the peripheral exposure apparatus as necessary, and an exposure process may be performed on a peripheral portion of the wafer W.

The wafer W transferred to the delivery device of the fifth block G5 is transferred by the wafer transfer devices 41 and 42 to the exposure apparatus and subjected to the exposure process with a predetermined pattern. Further, prior to the exposure process, the wafer W may be cleaned by the cleaning apparatus.

The wafer W subjected to the exposure process is transferred by the wafer transfer devices 41 and 42 to the delivery device of the fifth block G5. Thereafter, the wafer W is transferred by the wafer transfer device 33 to the thermal processing apparatus and subjected to a post-exposure bake process.

The wafer W subjected to the post-exposure bake process is transferred by the wafer transfer device 33 to the development processing apparatus and developed. After completion of the development, the wafer W is transferred by the wafer transfer device 33 to the thermal processing apparatus and subjected to a post-bake process.

Thereafter, the wafer W is transferred by the wafer transfer device 33 to the delivery device of the third block G3, and is transferred by the wafer transfer device 22 or 23 of the cassette station 2 to the cassette C on a predetermined cassette stage 21. Thus, a series of photolithography processes is completed.

In addition, the wafer processing system according to the present disclosure is not limited to the configuration and operation described above. For example, in the above-described embodiment, the wafer processing system 1 is directly connected to the exposure apparatus and transfers the wafer W between the interface station 4 and the exposure apparatus. However, the wafer processing system need not be directly connected to the exposure apparatus. In such a case, for example, after the wafer W is transferred from the cassette station 2 to the processing station 3 and subjected to a necessary process, the wafer W may be transferred back to the cassette station 2 for unloading to an outside of the system. Further, although the processing apparatuses were used as an example above, the processing apparatuses that are not required may not be provided in the wafer processing system, or a process performed on such apparatuses may be omitted.

### [Peripheral Processing Apparatus]

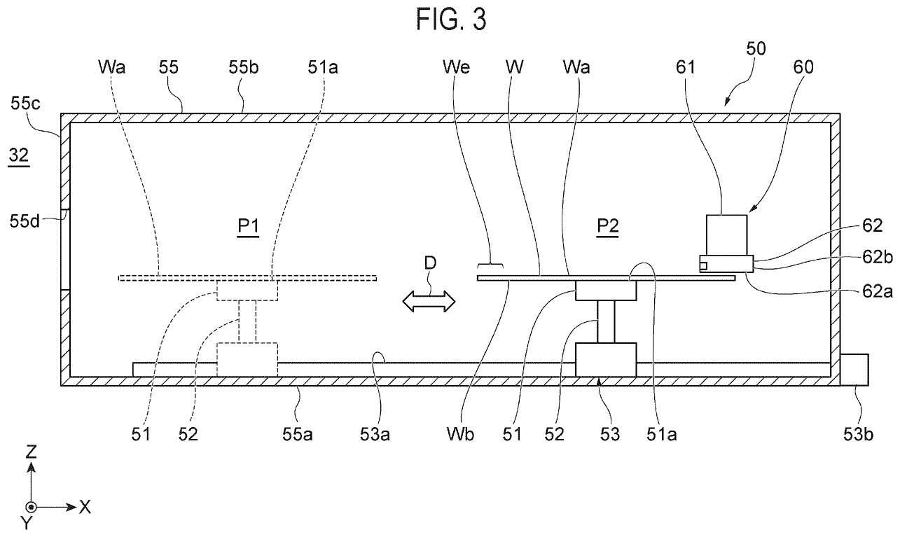

The wafer processing system 1 may further include a peripheral processing apparatus 50. An example of the peripheral processing apparatus 50 is the above-described peripheral exposure apparatus. As illustrated in FIG. 3, the peripheral processing apparatus 50 includes a holder 51 and a peripheral processor 60.

The holder 51 has a placement surface 51a on which the wafer W is placed. The placement surface 51a holds the wafer W such that a front surface Wa of the wafer W is horizontal. As one example, the placement surface 51a contacts a back surface Wb (a surface opposite to the front surface Wa) of the wafer W from below and holds the wafer W by suctioning the back surface Wb. The holder 51 is configured to be separatable from the peripheral processing apparatus 50. The wafer processing system 1 may include a plurality of holders 51 having different sizes (sizes in a direction along the back surface Wb). The plurality of holders 51 are selectively used according to a size of the process target wafer W.

The peripheral processing apparatus 50 performs a peripheral process on a peripheral portion We of the front surface Wa of the wafer W. The peripheral portion We is an annular region including a periphery of the front surface Wa and a vicinity of the periphery. As one example, the peripheral processing apparatus 50 performs an exposure process on the peripheral portion We of the wafer W in order to remove a peripheral portion of a resist film formed on the front surface Wa.

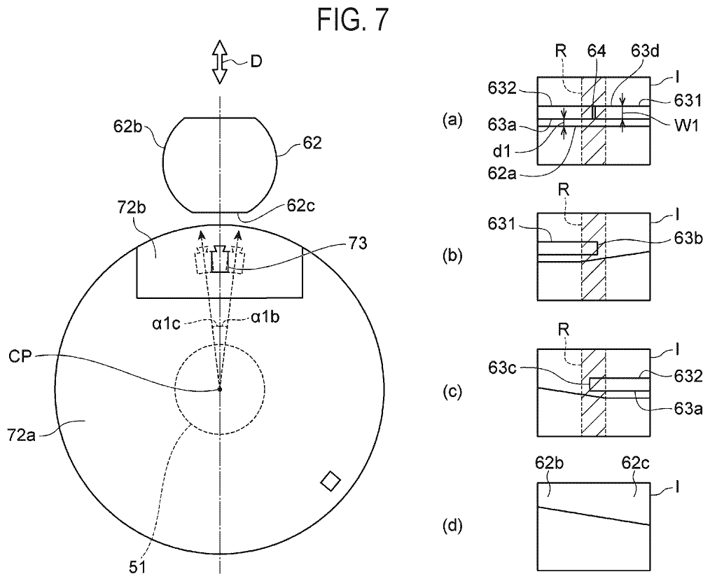

The peripheral processor 60 includes an irradiation head 61 and a mask 62. The mask 62 is detachably attached to the irradiation head 61. The mask 62 includes a facing surface 62a and a circumferential surface 62b. The facing surface 62a is a surface that faces the peripheral portion We in the vertical direction during the peripheral process. For example, the facing surface 62a faces vertically downward so as to face the peripheral portion We from above. The circumferential surface 62b is located above the facing surface 62a and faces the surroundings along the entire circumference around the Z-axis. The circumferential surface 62b has a cylindrical shape and includes a flat surface 62c formed by cutting out a portion of the cylinder (see FIG. 7). The flat surface 62c extends along the vertical direction (the Z direction).

An example of the above-described exposure process will now be described. Light for the exposure process is generated by a light source (not shown), such as an ultra-high-pressure mercury lamp, and is guided to the irradiation head 61 via a light-guiding member such as an optical fiber (not shown). The exposure light guided to the irradiation head 61 has its beam shape modified by an optical member such as a lens provided inside the irradiation head 61 and by a slit provided in the mask 62. The light whose beam shape has been modified as described above is irradiated from the facing surface 62a onto the peripheral portion We, thereby performing the peripheral process on the wafer W.

The peripheral processing apparatus 50 may further include a housing 55 that accommodates the holder 51, the peripheral processor 60, and the like. The housing 55 includes a bottom portion 55a, an upper portion 55b, and a peripheral wall 55c surrounding a space between the bottom portion 55a and the upper portion 55b. The housing 55 may be formed to extend along the X direction. A loading/unloading port 55d through which the wafer W is loaded and unloaded is formed in a portion of the peripheral wall 55c. For example, the loading/unloading port 55d opens toward one side of the housing 55 in a longitudinal direction of the housing 55 (for example, toward a negative X-axis direction). The wafer W is loaded into the housing 55 from the wafer transfer region 32 via the loading/unloading port 55d, subjected to the peripheral process, and then unloaded from an inside of the housing 55 to the wafer transfer region 32.

The peripheral processing apparatus 50 may further include a rotation driver 52. The rotation driver 52 is connected to the holder 51 from below. The rotation driver 52 rotates the holder 51 about a vertical axis (an axis along an out-of-plane direction of the front surface Wa) by means of a driving source such as an electric motor. The wafer W is placed on the holder 51 such that a rotation axis generated by the rotation driver 52 substantially coincides with a center of the wafer W. When the rotation driver 52 rotates the holder 51, the wafer W held by the holder 51 rotates about the vertical axis passing through the center of the wafer W (including a vicinity of the center).

The peripheral processing apparatus 50 may further include a linear driver 53. The linear driver 53 moves the holder 51 (and the rotation driver 52) along a displacement direction D that is perpendicular to the rotation axis of the holder 51. In the present embodiment, the displacement direction D is a direction extending between the peripheral processor 60 and the loading/unloading port 55d (a longitudinal direction of the housing 55, that is, the X direction). The linear driver 53 is, for example, of a ball-screw type in which the holder 51 is moved by rotating a ball screw 53a extending along the X direction using a movement motor 53b. The linear driver 53 may be a cylinder type that moves the holder 51 using a cylinder, or may be a belt type that moves the holder 51 using a belt and pulleys. The linear driver 53 is movable between a first position P1 in a vicinity of one end of the housing 55 in the X direction and a second position P2 in a vicinity of the other end of the housing 55 in the X direction. In the X direction, the loading/unloading port 55d of the housing 55, the first position P1, and the second position P2 are arranged in this order.

The wafer W loaded from the wafer transfer region 32 into the peripheral processing apparatus 50 is held by the holder 51 at the first position P1, and then transferred to the second position P2 by the linear driver 53. The facing surface 62a of the peripheral processor 60 faces the peripheral portion We of the wafer W transferred to the second position P2 from above. In the peripheral processor 60, while the peripheral processor 60 irradiates exposure light, the rotation driver 52 rotates the wafer W at the second position P2, thereby irradiating the exposure light over an entire circumference of the peripheral portion We of the wafer W.

### [Inspection System]

In the wafer processing system 1, a position of the facing surface 62a (for example, a position in the Z direction) affects a result of the peripheral process. For example, when the position of the facing surface 62a changes, a processing intensity, a processing range, and the like may change. In addition, during a transfer by the linear driver 53, there is a concern that the process cannot be executed because the wafer W and the mask 62 may come into contact with each other. Therefore, the wafer processing system 1 further includes an inspection system 70.

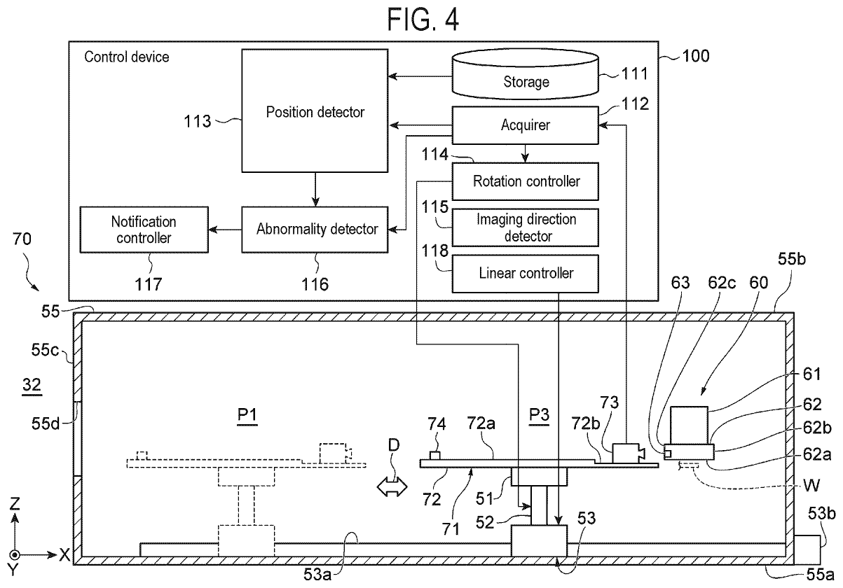

The inspection system 70 will be described with reference to FIG. 4. The inspection system 70 includes an inspection substrate 71, an imaging target 63, a storage 111, an acquirer 112, and a position detector 113. The inspection substrate 71 includes a support plate 72 and a capturer 73. The storage 111, the acquirer 112, and the position detector 113 are functional components (hereinafter referred to as “functional blocks”) and are constituted by the control device 100.

The support plate 72 is held by the holder 51 in place of the wafer W. The support plate 72 has, for example, the same outer shape (for example, a circular shape) as the wafer W in a plan view. Further, the support plate 72 may have an outer shape that is capable of being loaded into the housing 55 via the loading/unloading port 55d, similarly to the wafer W. The support plate 72 is formed of, for example, a material such as a ceramic.

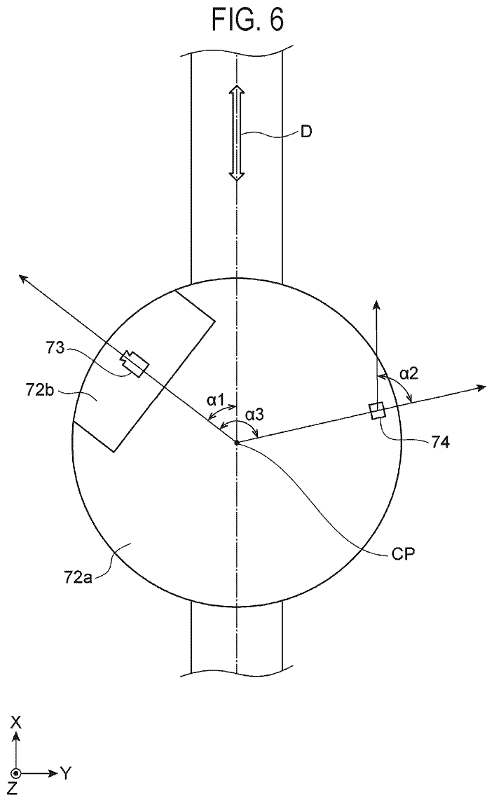

The capturer 73 is provided on the support plate 72 (on a front surface 72a) so as to capture images of surroundings of the support plate 72. That is, the support plate 72 supports the capturer 73. Here, the term “capturing images of surroundings of the support plate 72” means capturing images in a direction away from a center CP (see FIG. 6) of the support plate 72, and includes capturing images of a surrounding space above the support plate 72. For example, the capturer 73 is provided on a peripheral portion of the front surface 72a and is directed away from the center CP along a radial direction passing through the center CP. As the capturer 73, for example, a camera is used. An illumination (not shown) for illuminating an imaging region captured by the capturer 73 may be provided in a vicinity of the capturer 73. The capturer 73 may be provided on a recess 72b partially formed in the front surface 72a. By reducing a height of the capturer 73, it becomes easier to prevent the capturer 73 from colliding with surrounding objects during rotation or movement of the holder 51.

The inspection substrate 71 may further include an acceleration sensor 74. The acceleration sensor 74 is provided, for example, on the support plate 72. The acceleration sensor 74 detects direction and magnitude of acceleration generated in the support plate 72 along a direction parallel to the front surface 72a.

The imaging target 63 is provided so as to enter a field of view of the capturer 73. For example, when the capturer 73 is directed toward the peripheral processor 60, the imaging target 63 is provided on the circumferential surface 62b so as to enter the field of view of the capturer 73. For example, the flat surface 62c of the circumferential surface 62b faces the loading/unloading port 55d, and the imaging target 63 is provided on the flat surface 62c. The imaging target 63 has a rectangular shape extending in the vertical direction (the Z direction) and in a direction perpendicular to the displacement direction D (for example, the Y direction). The imaging target 63 has a first end 63b and a second end 63c in the Y direction, and an upper end 63d and a lower end 63a in the Z direction. As one example, the imaging target 63 is an unpainted portion formed by masking during a painting of the mask 62.

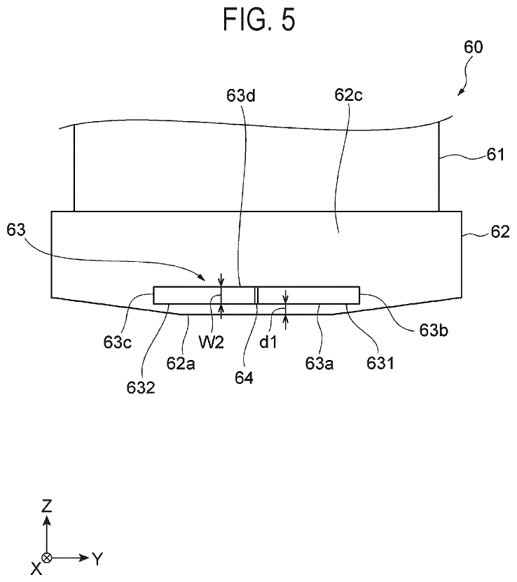

As illustrated in FIG. 5, the imaging target 63 may further include a mark 64 for positioning. The mark 64 is formed between the first end 63b and the second end 63c. For example, the mark 64 extends along the Z direction so as to connect the upper end 63d and the lower end 63a. Therefore, the imaging target 63 is divided into a first portion 631 and a second portion 632 arranged in the horizontal direction. The mark 64 may be located at an intermediate position between the first end 63b and the second end 63c. For example, a distance between the first end 63b and the mark 64 is equal to a distance between the second end 63c and the mark 64.

The storage 111 stores a positional relationship between the imaging target 63 and the facing surface 62a. The positional relationship is, for example, a positional relationship in the vertical direction between the imaging target 63 and the facing surface 62a. The positional relationship may be a relative position (for example, a relative height) of the facing surface 62a with respect to the imaging target 63, or may be a relative position (for example, a relative height) of the imaging target 63 with respect to the facing surface 62a. As one example, the storage 111 stores a vertical relationship between the lower end 63a of the imaging target 63 and the facing surface 62a, and a distance d1 in the vertical direction between the lower end 63a and the facing surface 62a. In addition, as illustrated in FIG. 5, when the facing surface 62a is not configured as a plane, a lowermost portion of the facing surface 62a in the vertical direction is regarded as a position of the facing surface 62a.

The acquirer 112 acquires an image I including the imaging target 63 from the capturer 73. The image I is, for example, a digital image. Further, as one example, the image I has a VGA size of 480 pixels in a vertical direction by 640 pixels in a horizontal direction.

The position detector 113 detects a position of the facing surface 62a based on a position of the imaging target 63 in the image I and a positional relationship (for example, the distance d1). For example, the position detector 113 detects an actual position of the lower end 63a of the imaging target 63 from a position of a pixel in the image I in which the lower end 63a of the imaging target 63 appears. The position detector 113 detects the position of the facing surface 62a based on the detected actual position of the lower end 63a, the upper-lower positional relationship between the lower end 63a and the facing surface 62a, and the distance d1 from the lower end 63a to the facing surface 62a.

The inspection system 70 may further include a rotation controller 114. The rotation controller 114 is a functional block constituted by the control device 100. The rotation controller 114 controls the rotation driver 52 so as to direct the capturer 73 toward the imaging target 63. In addition, the inspection system 70 may further include an imaging direction detector 115. The imaging direction detector 115 detects an inclination α1 of an imaging direction of the capturer 73 with respect to the displacement direction D based on a detection result of the acceleration sensor 74.

The detection of the inclination α1 will be described with reference to FIG. 6. As described above, the acceleration sensor 74 detects the direction and magnitude of the acceleration generated in the support plate 72 along the direction parallel to the front surface 72a. When the holder 51 holding the support plate 72 moves along the displacement direction D, the imaging direction detector 115 detects the direction of acceleration detected by the acceleration sensor 74, as an inclination α2 of the displacement direction D with respect to the acceleration sensor 74. The imaging direction detector 115 calculates the inclination α1 of the imaging direction with respect to the displacement direction D based on the detected inclination α2 and an inclination α3 of an imaging direction with respect to the acceleration sensor 74. The inclination α3 is stored in advance. For example, the imaging direction detector 115 calculates the inclination α1 of the imaging direction with respect to the displacement direction D based on a difference between the inclination α2 and the inclination α3. The rotation controller 114 may control the rotation driver 52 to direct the capturer 73 toward the imaging target 63 based on the detection result of the inclination α1. For example, the rotation controller 114 rotates the holder 51 such that the inclination α1 becomes zero.

As illustrated in (a) of FIG. 7, the rotation controller 114 may further control the rotation driver 52 such that the mark 64 of the imaging target 63 enters a predetermined range R within the image I. As one example, the predetermined range R is set in units of pixels in a horizontal direction in the image I.

When the mark 64 is located outside the image I and the above-described first end 63b is within the image I, the rotation controller 114 rotates the holder 51 in a direction in which the capturer 73 is displaced from the first end 63b toward the above-described second end 63c, and when the mark 64 is located outside the image I and the second end 63c is within the image I, the rotation controller 114 rotates the holder 51 in a direction in which the capturer 73 is displaced from the second end 63c toward the first end 63b, thereby moving the mark 64 into the predetermined range R.

FIG. 7 in (b) illustrates a state in which, in the image I, the mark 64 is not included and the first end 63b is included. At this time, the inclination α1 of the capturer 73 is indicated as α1b in FIG. 7. When the image I is in the above-described state, the rotation controller 114 rotates the holder 51 in the direction in which the capturer 73 is displaced from the first end 63b toward the second end 63c, thereby moving the mark 64 into the predetermined range R as illustrated in (a) of FIG. 7.

FIG. 7 in (c) illustrates a state in which, in the image I, the mark 64 is not included and the second end 63c is included. At this time, the inclination α1 of the capturer 73 is indicated as α1c in FIG. 7. When the image I is in the above-described state, the rotation controller 114 rotates the holder 51 in the direction in which the capturer 73 is displaced from the second end 63c toward the first end 63b, thereby moving the mark 64 into the predetermined range R as illustrated in (a) of FIG. 7.

The inspection system 70 may further include an abnormality detector 116. The abnormality detector 116 is a functional block constituted by the control device 100. The abnormality detector 116 detects various abnormalities in the inspection system 70. As one example, the abnormality detector 116 detects an abnormality when, after the rotation controller 114 rotates the holder 51 by the rotation driver 52 so as to direct the capturer 73 toward the imaging target 63 based on the detection result of the inclination α1, the imaging target 63 is not included in the image I. FIG. 7 in (d) illustrates a state in which the imaging target 63 is not included in the image I.

In addition, the imaging target 63 is not limited to the above-described configuration. For example, the imaging target 63 may be a cross-shaped mark. In this case, a vertical line of the cross may be used as the mark 64, and both ends of a horizontal line of the cross may be used as the above-described first end 63b and second end 63c. The mark 64 does not necessarily have to extend in a vertical direction and may be a point. The imaging target 63 may have three elements arranged in a horizontal direction in a form different from the first end 63b, the mark 64, and the second end 63c. The three elements may be three points arranged in the horizontal direction, or three line segments each extending in a vertical direction. Instead of painting a periphery of the imaging target 63 and leaving the imaging target 63 unpainted, the periphery may be left unpainted and the imaging target 63 may be formed by painting.

The inspection system 70 may further include a notification controller 117. The notification controller 117 is a functional block constituted by the control device 100. When an abnormality is detected by the abnormality detector 116, the notification controller 117 operates a notification device (not shown) to notify an external entity of the abnormality. The notification device may be, for example, a monitor, and the notification controller 117 transmits a signal to the notification device to cause the monitor to display that the abnormality has occurred. Means for indicating that the abnormality has occurred is not limited to visual information, and may be auditory information such as a buzzer.

The inspection system 70 may further include a linear controller 118. The linear controller 118 is a functional block constituted by the control device 100. The linear controller 118 adjusts a position of the capturer 73 by the linear driver 53 such that the imaging target 63 falls within a depth of focus of the capturer 73. The depth of focus refers to a range within which a required resolution can be maintained on a line along an optical axis center of the capturer 73. As one example, the linear controller 118 controls the linear driver 53 such that the holder 51 is positioned at a third position P3. When the holder 51 is positioned at the third position P3, the imaging target 63 falls within the depth of focus of the capturer 73. In the present embodiment, in a state in which the holder 51 is positioned at the third position P3, a distance in the X direction between the inspection substrate 71 and the mask 62 is approximately 3 mm.

The inspection system 70 may detect a position of the facing surface 62a by the above-described position detector 113 in a state in which the holder 51 is positioned at the third position P3 as described above. In addition, the position detector 113 may detect the position of the facing surface 62a further based on a relationship between a size of the imaging target 63 in the image I and an actual size of the imaging target 63.

For example, the position detector 113 may detect the position of the facing surface 62a further based on a relationship between a width W1 (see FIG. 7) of the imaging target 63 in the image I and an actual width W2 (see FIG. 5) of the imaging target 63 in a direction perpendicular to the facing surface 62a. When the imaging target 63 has a rectangular shape, each of the width W1 and the width W2 is, for example, a distance between the upper end 63d and the lower end 63a. When the width W2 is known, by measuring the number of pixels of the width W1 in the image I, a coefficient X for converting one pixel of the image I into an actual distance can be determined from the number of pixels and the width W2. Accordingly, since a position of the lower end 63a of the imaging target 63 in the vertical direction can be detected with high accuracy from the image I, the position of the facing surface 62a can be detected with higher accuracy.

In addition, a width of the imaging target 63 in the direction perpendicular to the facing surface 62a is not limited to the distance between the upper end 63d and the lower end 63a of the rectangular imaging target 63. For example, in the case of the cross-shaped imaging target 63 described above, a length of the vertical line can be used as the width of the imaging target 63. In addition, when the imaging target 63 has the three line segments arranged in the horizontal direction, a length of at least one of the three line segments can be used as the width of the imaging target 63. The imaging target 63 may have two points arranged in the vertical direction. In this case, a distance between the two points can be used as the width of the imaging target 63. That is, the imaging target 63 needs to have only two elements arranged apart from each other in the vertical direction, or an element having a finite size in the vertical direction, similarly to the upper end 63d and the lower end 63a.

The position detector 113 may detect, as the position of the facing surface 62a, a distance d2 between the facing surface 62a and a plane PL on which the front surface Wa of the wafer W is positioned when the wafer W is held by the holder 51. As one example, the position detector 113 may detect the distance d2 between the plane PL and the facing surface 62a based on the position of the imaging target 63 in the image I, the positional relationship (the vertical relationship and the distance d1), the relationship between the size of the imaging target 63 in the image I and the actual size of the imaging target 63, a position of the capturer 73 relative to the holder 51, and a thickness T of the wafer W.

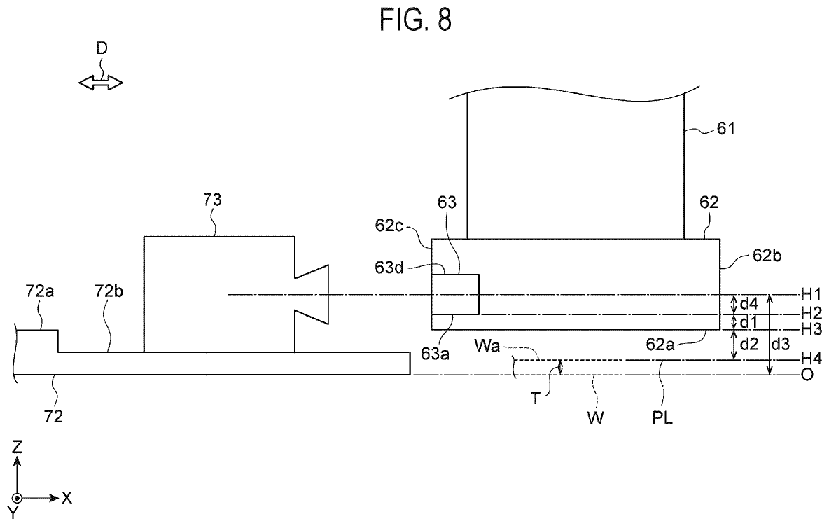

The above detection procedure will be described in detail with reference to FIG. 8. Here, a distance in the vertical direction is simply referred to as a distance. In addition, a height at which the placement surface 51a of the holder 51 is located is defined as a reference height O. The position of the capturer 73 relative to the holder 51 is, for example, a distance d3 between the placement surface 51a of the holder 51 and a center of a light-receiving element of the capturer 73, and corresponds to a height H1 in FIG. 8.

Next, in the image I, a pixel number PN from a center pixel of the image I to the lower end 63a of the imaging target 63 is measured. Then, the coefficient X for converting one pixel into the actual distance is calculated from the relationship between the size of the imaging target 63 in the image I and the actual size of the imaging target 63, and a distance d4 between the height H1 and the lower end 63a can be obtained by multiplying the coefficient X by the pixel number PN. Accordingly, a height H2 of the lower end 63a is obtained.

Next, based on the positional relationship stored in the storage 111 between the imaging target 63 and the facing surface 62a (the distance d1 between the lower end 63a and the facing surface 62a), and the height H2, a height H3 of the facing surface 62a relative to the reference height O is obtained.

Next, based on the thickness T of the wafer W, a height H4 of the front surface Wa (that is, a height of the plane PL) relative to the reference height O is obtained. Then, based on the height H3 and the height H4 obtained through the above procedure, the distance d2 between the plane PL and the facing surface 62a is obtained. In summary, the distance d2 is calculated by the following equation:

d2=d3+PN×X−d1−T (1)

Further, the lower end 63a does not necessarily have to be used as the position of the imaging target 63, and the upper end 63d or the center of the imaging target 63 may be used instead.

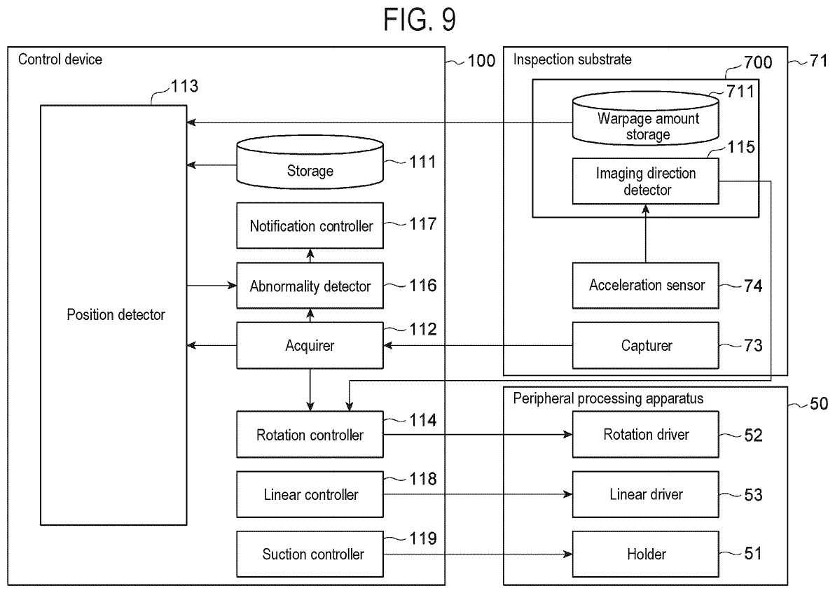

FIG. 9 illustrates a modification of a configuration of the inspection system 70. As illustrated in FIG. 9, the imaging direction detector 115 may be provided in the inspection substrate 71. For example, the inspection substrate 71 may further include an arithmetic device 700, and the imaging direction detector 115 may be a functional block constituted by the arithmetic device 700.

The inspection system 70 may further include a warpage amount storage 711. The warpage amount storage 711 stores a warpage amount of the wafer W when the wafer W is held by the holder 51. The warpage amount is, for example, a downward displacement amount of the peripheral portion We caused by a warpage of the wafer W. The warpage amount may be measured in advance by using a laser displacement meter or the like in a state in which a wafer for adjustment is placed on the holder 51. In addition, since the warpage amount varies depending on a size of the holder 51, the warpage amount storage 711 may store a plurality of warpage amounts corresponding to a plurality of sizes of the holder 51. As illustrated, the warpage amount storage 711 may be provided in the inspection substrate 71. For example, the warpage amount storage 711 may be a functional block constituted by the arithmetic device 700.

The position detector 113 may detect the distance d2 between the plane PL and the facing surface 62a further based on the above-described warpage amount. For example, the position detector 113 may detect the distance d2 by adding the warpage amount to the distance d2 calculated by the above Equation (1). The position detector 113 may acquire size information of the holder 51, extract the warpage amount of the wafer W corresponding to the size of the holder 51 from the warpage amount storage 711, and use the extracted warpage amount for detection of the distance d2.

The warpage amount storage 711 may further store a warpage amount of the inspection substrate 71 in addition to the warpage amount of the wafer W. The warpage amount of the inspection substrate 71 is, for example, a downward displacement amount of the capturer 73 caused by a warpage of the inspection substrate 71. The warpage amount of the inspection substrate 71 may also be measured in advance by using a laser displacement meter or the like. The warpage amount storage 711 may store, for the inspection substrate 71 as well, the plurality of warpage amounts corresponding to the plurality of sizes of the holder 51.

When the warpage amount storage 711 further stores the warpage amount of the inspection substrate 71, the position detector 113 may detect the distance d2 described above based on both the warpage amount of the wafer W and the warpage amount of the inspection substrate 71. For example, the position detector 113 may detect the distance d2 by adding the warpage amount of the wafer W to the distance d2 calculated by the above Equation (1) and subtracting the warpage amount of the inspection substrate 71 from the distance d2. The position detector 113 may acquire the size information of the holder 51, extract the warpage amount of the wafer W and the warpage amount of the inspection substrate 71 corresponding to the size of the holder 51 from the warpage amount storage 711, and use the extracted warpage amounts for detection of the distance d2.

The abnormality detector 116 may further detect an abnormality when the distance d2 between the plane PL and the facing surface 62a is outside a predetermined range. As one example, the abnormality detector 116 is set to detect an abnormality when the distance d2 is 0.2 mm or less. Therefore, when a peripheral process is performed on the wafer W by the peripheral processing apparatus 50, contact between the facing surface 62a and the wafer W is suppressed. A threshold value of the distance d2 for determining an abnormality may be set in consideration of various tolerances that may occur in the inspection system 70 with respect to a desired distance d2. Further, the abnormality detector 116 may also detect an abnormality when the distance d2 is larger than a predetermined threshold value.

The inspection system 70 may further include a suction controller 119. The suction controller 119 is a functional block constituted by the control device 100. The suction controller 119 releases suction of the inspection substrate 71 suctioned by the holder 51, and causes the holder 51 to re-suction the inspection substrate 71. During transfer of the inspection substrate 71 into the wafer processing system 1, a portion of heat generated by a CPU (not shown) provided on the inspection substrate 71 may be transferred to the holder 51, causing an expansion of the support plate 72 and the like and resulting in a warpage. By once releasing the inspection substrate 71 suction-held by the holder 51 and then re-suctioning the inspection substrate 71 as described above, the warpage generated as described above can be suppressed. The position detector 113 may detect the position of the facing surface 62a based on an image I acquired after the inspection substrate 71 is re-suctioned by the holder 51.

In addition, the use of the inspection substrate 71 is not limited to the inspection of the peripheral processing apparatus 50. For example, the inspection substrate 71 may be used for an inspection of a film forming apparatus for patterning or a development processing apparatus. For example, the inspection substrate 71 may be used to inspect whether or not a height of a member (such as a circular cup provided so as to surround a wafer) constituting the development processing apparatus is appropriate. Further, in this case, at least one of the functional blocks described above may be used. For example, the inspection substrate 71 may direct the capturer 73 to a desired direction based on a detection result by the imaging direction detector 115 and an image I captured by the capturer 73 that includes a processing nozzle of the development processing apparatus or the above-described cup.

In addition, in the above examples, the functional blocks constituted by the control device 100 may instead be constituted by the arithmetic device 700. Similarly, in the above examples, the functional blocks constituted by the arithmetic device 700 may instead be constituted by the control device 100. For example, the acquirer 112 may be constituted by the arithmetic device 700 of the inspection substrate 71, and the warpage amount storage 711 may be constituted by the control device 100.

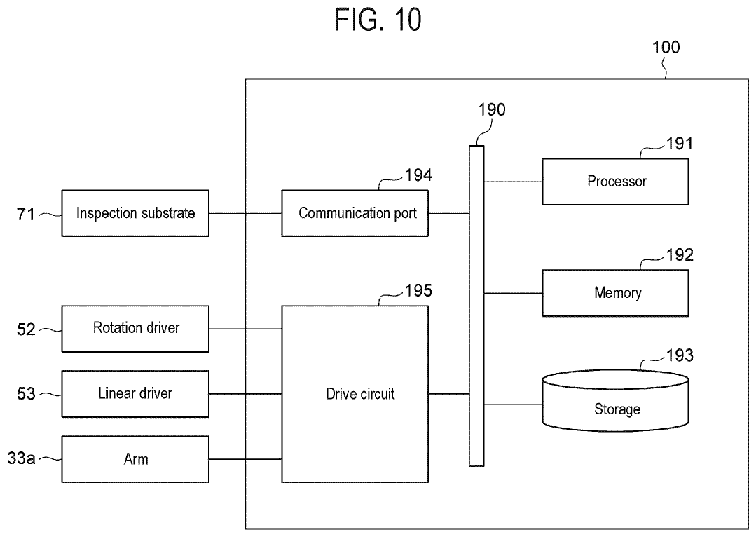

FIG. 10 is a block diagram illustrating an example of a hardware configuration of the control device 100. As illustrated in FIG. 10, the control device includes a circuit 190. The circuit 190 includes a processor 191, a memory 192, a storage 193, a communication port 194, and a drive circuit 195.

The storage 193 includes, for example, one or more non-volatile and non-transitory computer-readable storage medium. The non-volatile storage medium includes one or more storage devices. Examples of the one or more storage devices may include a hard disk drive, a solid state drive, a flash memory, and the like. The non-transitory storage medium may include a portable storage medium such as an optical disc. The storage 193 stores programs that cause the control device 100 to execute holding the support plate 72 by the holder 51, capturing the images of the surroundings of the support plate 72 by the capturer 73 provided on the support plate 72, storing the positional relationship between the imaging target 63, which is provided on the peripheral processor 60 so as to enter the field of view of the capturer 73, and the facing surface 62a, acquiring the image I including the imaging target 63 by the capturer 73, and detecting the position of the facing surface 62a based on the position of the imaging target 63 in the image I and the positional relationship. For example, the storage 193 stores programs for causing the control device 100 to configure the respective functional blocks described above.

The memory 192 includes one or more volatile and non-transitory computer-readable storage medium. The volatile storage medium includes one or more memory devices, such as a random access memory. The memory 192 temporarily stores programs loaded from the storage 193. The processor 191 includes one or more arithmetic devices, such as a central processing unit (CPU) or a graphics processing unit (GPU). The processor 191 executes the programs loaded into the memory 192 to configure the respective functional blocks described above in the control device 100. The processor 191 may temporarily store calculation results in the memory 192.

The communication port 194 performs wireless communication between the inspection substrate 71 in accordance with commands from the processor 191. Examples of the wireless communication may include Wi-Fi (registered trademark) and Bluetooth (registered trademark).

The drive circuit 195 controls, in response to requests from the processor 191, the rotation driver 52, the linear driver 53, and the arms provided in the respective wafer transfer devices 22, 23, 33, 41, and 42 (not shown except for the transfer arm 33a of the wafer transfer device 33).

### [Inspection Procedure]

As an example of an inspection method, an inspection procedure executed by the inspection system 70 is illustrated. The inspection procedure includes: holding, by the holder 51, the support plate 72 constituting the inspection substrate 71 in place of the wafer W; capturing the images of the surroundings of the support plate 72 by the capturer 73 provided on the support plate 72; storing the positional relationship between the imaging target 63, which is provided on the peripheral processor 60 so as to enter the field of view of the capturer 73, and the facing surface 62a; acquiring the image I including the imaging target 63 by the capturer 73; and detecting the position of the facing surface 62a based on the position of the imaging target 63 in the image I and the positional relationship.

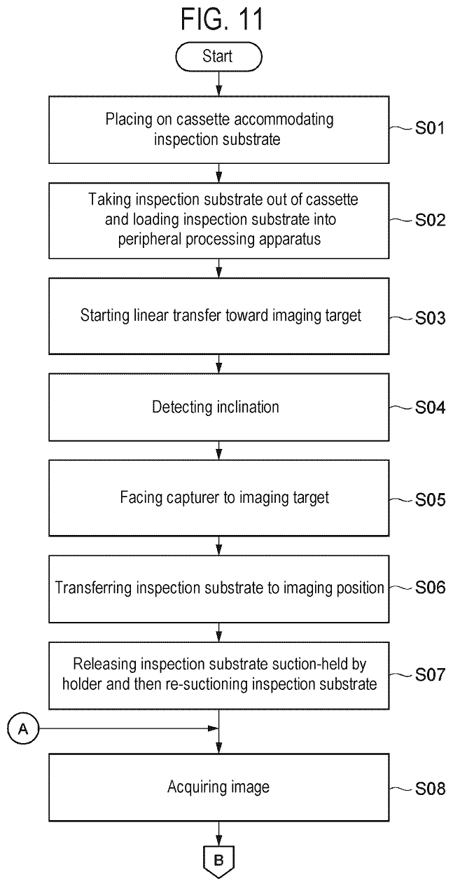

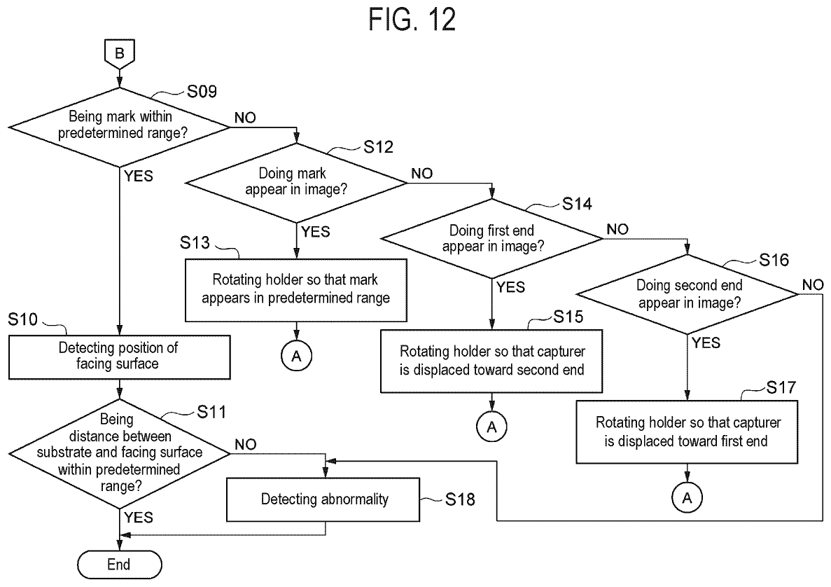

FIGS. 11 and 12 are flowcharts illustrating an example of a procedure for detecting the position of the facing surface 62a. The wafer processing system 1 executes steps S01 and S02. In step S01, a cassette C accommodating the inspection substrate 71 is placed on the cassette stage 21 of the cassette station 2. In step S02, the wafer transfer device 22 or the wafer transfer device 23 takes the inspection substrate 71 out of the cassette C, and the inspection substrate 71 is loaded into the peripheral processing apparatus 50 via the block G3, the wafer transfer device 33, and the loading/unloading port 55d.

Next, the inspection system 70 executes steps S03, S04, S05, S06, and S07. In step S03, the linear controller 118 controls the linear driver 53 such that the inspection substrate 71 is transferred from the first position P1 toward the third position P3. In step S04, the imaging direction detector 115 detects the inclination α1 of the imaging direction of the capturer 73 with respect to the displacement direction D based on the detection result of the acceleration sensor 74. In step S05, the rotation controller 114 controls the rotation driver 52 so that the capturer 73 faces the imaging target 63. In step S06, the linear controller 118 controls the linear driver 53 so that the imaging target 63 falls within the depth of focus of the capturer 73. In step S07, the suction controller 119 controls the holder 51 so as to first release the inspection substrate 71 suction-held by the holder 51 and then re-suction the inspection substrate 71.

Next, the inspection system 70 executes steps S08 and S09. In step S08, the acquirer 112 acquires the image I including the imaging target 63 from the capturer 73. In step S09, the rotation controller 114 determines whether or not the position of the mark 64 in the image I is within the predetermined range R.

When it is determined in step S09 that the position of the mark 64 in the image I is within the predetermined range R, the inspection system executes steps S10 and S11. In step S10, the position detector 113 detects, as the position of the facing surface 62a, the distance d2 between the facing surface 62a and the plane PL on which the front surface Wa of the wafer Wis positioned when the wafer W is held by the holder 51. In step S11, the abnormality detector 116 determines whether or not the distance d2 between the plane PL and the facing surface 62a is within a predetermined range.

When it is determined in step S09 that the position of the mark 64 in the image I is outside the predetermined range R, the inspection system executes step S12. In step S12, the rotation controller 114 determines whether or not the mark 64 appears in the image I.

When it is determined in step S12 that the mark 64 appears in the image I, the inspection system 70 executes step S13. In step S13, the rotation controller 114 controls the rotation driver 52 so that the mark 64 enters the predetermined range R. After executing step S13, the inspection system 70 executes step S08 again.

When it is determined in step S12 that the mark 64 does not appear in the image I, the inspection system 70 executes step S14. In step S14, the rotation controller 114 determines whether or not the first end 63b appears in the image I.

When it is determined in step S14 that the first end 63b appears in the image I, the inspection system 70 executes step S15. In step S15, the rotation controller 114 rotates the holder 51 so that the capturer 73 is displaced from the first end 63b toward the second end 63c. After executing step S15, the inspection system 70 executes step S08 again.

When it is determined in step S14 that the first end 63b does not appear in the image I, the inspection system 70 executes step S16. In step S16, the rotation controller 114 determines whether or not the second end 63c appears in the image I.

When it is determined in step S16 that the second end 63c appears in the image I, the inspection system 70 executes step S17. In step S17, the rotation controller 114 rotates the holder 51 so that the capturer 73 is displaced from the second end 63c toward the first end 63b. After executing step S17, the inspection system 70 executes step S08 again.

When it is determined in step S11 that the distance d2 between the plane PL and the facing surface 62a is outside the predetermined range, the inspection system 70 executes step S18. In step S18, upon detection of an abnormality by the abnormality detector 116, the notification device which notifies an external entity of the abnormality is operated by the notification controller 117. The inspection system 70 similarly executes step S18 when it is determined in step S16 that the second end 63c does not appear in the image I.

When it is determined in step S11 that the distance d2 between the plane PL and the facing surface 62a is within the predetermined range, or after execution of step S18, the inspection system 70 terminates the detection of the position of the facing surface 62a.

### SUMMARY

The embodiments exemplified above include the following configurations.

(1) An inspection system 70 for inspecting a wafer processing system 1 including a holder 51 that holds a wafer W, and a peripheral processor 60, which has a facing surface 62a facing a peripheral portion We of a front surface Wa of the wafer W held by the holder 51 and performs a process on the peripheral portion We, including: an inspection substrate 71 including a support plate 72 held by the holder 51 in place of the wafer W, and a capturer 73 provided on the support plate 72 to capture images of surroundings of the support plate 72; a storage 111 configured to store a positional relationship between the facing surface 62a and an imaging target 63 provided on the peripheral processor 60 such that the imaging target 63 falls within a field of view of the capturer 73; an acquirer 112 configured to acquire an image I including the imaging target 63 from the capturer 73; and a position detector 113 configured to detect a position of the facing surface 62a based on a position of the imaging target 63 in the image I and the positional relationship.

In the wafer processing system 1, the position of the facing surface 62a affects a result of process applied to the wafer W. In particular, when the process is performed with a small distance between the facing surface 62a and the wafer W, even a slight error significantly affects the processing result. Therefore, it is desirable to detect the position of the facing surface 62a and manage the positional relationship between the wafer W and the facing surface 62a based on a detection result. In order to avoid a complication of the processing apparatus for detecting the position of the facing surface 62a, it is conceivable not to install a sensor or the like for detecting the facing surface 62a, but instead to provide a sensor on the support plate 72. When the sensor is provided on the support plate 72, it is possible to load the sensor easily into the apparatus by using a substrate transfer system and detect the facing surface 62a.

However, there is a case that the facing surface 62a is located at a position slightly separated from the front surface Wa of the wafer W. In such a case, the sensor installed on the support plate 72 may not be able to detect the facing surface 62a due to a physical size or the like of the sensor. In contrast, according to the above-described system configuration, since the position of the imaging target 63 can be directly captured by the sensor (the capturer 73) provided on the support plate 72, and the positional relationship between the imaging target 63 and the facing surface 62a is stored in the storage 111, the position of the facing surface 62a can be detected with high accuracy based on the image I including the imaging target 63 captured by the capturer 73 and the positional relationship between the imaging target 63 and the facing surface 62a, even when the facing surface 62a cannot be directly detected. Therefore, the above-described system configuration is effective in improving stability of the process on the peripheral portion We.

(2) The inspection system 70 of Item (1), wherein the wafer processing system 1 further includes a rotation driver 52 configured to rotate the holder 51, the inspection system 70 further including: a rotation controller 114 configured to direct the capturer 73 toward the imaging target 63 by the rotation driver 52, wherein the acquirer 112 acquires the image I from the capturer 73 directed toward the imaging target 63 by the rotation controller 114.

In this case, since the capturer 73 can be directed toward the imaging target 63 by the rotation driver 52, it is not necessary to adjust the direction of the capturer 73 before the holder 51 holds the support plate 72. Therefore, the inspection substrate 71 can be easily transferred.

(3) The inspection system 70 of Item (2), wherein the imaging target 63 has a positioning mark 64, wherein the rotation controller 114 further controls the rotation driver 52 based on the image I such that the mark 64 falls within a predetermined range R in the image I, and wherein the position detector 113 detects the position of the facing surface 62a based on the position of the imaging target 63 in the image I acquired in a state in which the mark 64 falls within the predetermined range R, and the positional relationship.

In this case, since the image I is acquired in a state where the positioning mark 64 of the imaging target 63 falls within the predetermined range R, deviation of a relative position of the capturer 73 with respect to the imaging target 63 for each timing when an inspection is performed can be suppressed. Accordingly, a detection accuracy of the position of the facing surface 62a can be improved.

(4) The inspection system 70 of Item (3), wherein the mark 64 is located between a first end 63b and a second end 63c of the imaging target 63, and wherein the rotation controller 114 is configured to move the mark 64 into the predetermined range R by: rotating the holder 51 in a direction in which the capturer 73 is displaced from the first end 63b toward the second end 63c when the mark 64 is outside the image I and the first end 63b is within the image I; and rotating the holder 51 in a direction in which the capturer 73 is displaced from the second end 63c toward the first end 63b when the mark 64 is outside the image I and the second end 63c is within the image I.

Thus, when the mark 64 is located outside the image I, a direction in which the holder 51 should be rotated can be easily specified depending on whether the first end 63b or the second end 63c is present in the image I.

(5) The inspection system 70 of any one of Items (2) to (4), wherein the wafer processing system 1 further includes a linear driver 53 configured to move the holder 51 toward the peripheral processor 60 along a displacement direction D perpendicular to a rotation axis of the holder 51, and wherein the inspection substrate 70 further includes an acceleration sensor 74 provided on the support plate 72, the inspection system further including: an imaging direction detector 115 configured to detect an inclination α1 of a field-of-view direction of the capturer 73 with respect to the displacement direction D based on a detection result of the acceleration sensor 74, wherein the rotation controller 114 directs the capturer 73 toward the imaging target 63 by the rotation driver 52 based on a detection result of the inclination α1.

In this case, before the image I of the imaging target 63 is obtained by the capturer 73, the capturer 73 can be directed toward the imaging target 63 at an early stage based on an inclination of the field-of-view direction with respect to the displacement direction D.

(6) The inspection system 70 of Item (5), further includes: an abnormality detector 116 configured to detect an abnormality when the imaging target 63 is not included in the image I after the rotation controller 114 rotates the holder 51 by the rotation driver 52 to direct the capturer 73 toward the imaging target 63 based on the detection result of the inclination α1.

In this case, the abnormality of the inspection system 70 can be easily detected based on the fact that the imaging target 63 is not included in the image I despite the capturer 73 being directed toward the imaging target 63.

(7) The inspection system 70 of Item (5) or (6), wherein the imaging direction detector 115 is provided on the inspection substrate 71.

In this case, information of the inclination α1 output from the inspection substrate 71 can be directly used to adjust the direction of the capturer 73. Accordingly, the inspection system 70 can be easily constructed.

(8) The inspection system 70 of any one of Items (1) to (7), wherein the wafer processing system 1 further includes the linear driver 53 configured to move the holder 51 toward the peripheral processor 60 along the displacement direction D perpendicular to the rotation axis of the holder 51, the inspection system further including: a linear controller 118 configured to adjust a position of the capturer 73 by the linear driver 53 such that the imaging target 63 falls within a depth of focus of the capturer 73, and wherein the acquirer 112 acquires the image I from the capturer 73 in a state in which the imaging target 63 falls within the depth of focus.

In this case, since the imaging target 63 appears clearly in the image I, the detection accuracy of the position of the facing surface 62a can be improved.

(9) The inspection system 70 of any one of Items (1) to (8), wherein the position detector 113 detects the position of the facing surface 62a further based on a relationship between a size of the imaging target 63 in the image I and an actual size of the imaging target 63.

In this case, a variation in the relationship between the position of the imaging target 63 in the image I and the actual position of the imaging target 63 due to an imaging magnification can be suppressed, thereby further improving the detection accuracy of the position of the facing surface 62a.

(10) The inspection system 70 of any one of Items (1) to (9), wherein the position detector 113 detects the position of the facing surface 62a further based on a relationship between a width W1 of the imaging target 63 in the image I and an actual width W2 of the imaging target in a direction perpendicular to the facing surface 62a.

In this case, based on an imaging magnification in the direction perpendicular to the facing surface 62a, the detection accuracy of the position of the facing surface 62a in the direction perpendicular to the facing surface 62a can be further improved.

(11) The inspection system 70 of any one of Items (1) to (10), wherein the position detector 113 detects, as the position of the facing surface 62a, a distance d2 between the facing surface 62a and a plane PL on which the front surface Wa of the wafer W held by the holder 51 is positioned.

In this case, a detection result that facilitates a determination of whether or not the position of the facing surface 62a is appropriate can be output.

(12) The inspection system 70 of Item (11), wherein the position detector 113 detects a distance d2 between the facing surface 62a and the plane PL based on the position of the imaging target 63 in the image I, the positional relationship, a relationship between a size of the imaging target 63 in the image I and an actual size of the imaging target 63, a position of the capturer 73 with respect to the holder 51, and a thickness T of the wafer W.

In this case, the distance d2 between the plane PL and the facing surface 62a can be detected with higher accuracy.

(13) The inspection system 70 of Item (11) or (12), further includes: a warpage amount storage 711 configured to store a warpage amount of the wafer W in a state in which the wafer W is held by the holder 51, wherein the position detector 113 detects the distance d2 between the facing surface 62a and the plane PL further based on the warpage amount.

In this case, by reflecting the warpage amount in a position of the plane PL, the distance d2 between the plane PL and the facing surface 62a can be detected with higher accuracy.

(14) The inspection system 70 of Item (13), wherein the warpage amount storage 711 stores a plurality of warpage amounts respectively corresponding to a plurality of sizes of the holder 51, and wherein the position detector 113 detects the distance d2 between the facing surface 62a and the plane PL further based on a warpage amount corresponding to the actual size of the holder 51 among the plurality of warpage amounts.

In this case, by reflecting differences in the warpage amount depending on the size of the wafer W in the position of the plane PL, the distance d2 between the plane PL and the facing surface 62a can be detected with higher accuracy.

(15) The inspection system 70 of Item (13) or (14), wherein the warpage amount storage 711 is provided on the inspection substrate 71.

In this case, since the warpage amount can be obtained from the inspection substrate 71, the inspection system 70 that takes the warpage amount into consideration can be easily constructed.

(16) The inspection system 70 of any one of Items (11) to (15), further includes: an abnormality detector 116 configured to detect an abnormality when the distance d2 between the facing surface 62a and the plane PL is outside a predetermined range.

In this case, by performing the abnormality detection by the system, human errors such as oversight can be prevented.

(17) The inspection system 70 of any one of Items (1) to (16), wherein the holder 51 is configured to hold the wafer W or the support plate 72 by suction, the inspection system further including: a suction controller 119 configured to release the suction of the support plate 72 suctioned by the holder 51, and cause the holder 51 to re-suction the support plate 72, and wherein the position detector 113 detects the position of the facing surface 62a based on an image I acquired after the holder 51 re-suctions the support plate 72.

In this case, a strain accumulated in the inspection substrate 71 due to the suction by the holder 51 before the acquisition of the image I can be released prior to the acquisition of the image I. As a result, a variation in the image I due to the strain of the inspection substrate 71 can be suppressed, thereby improving the detection accuracy of the position of the facing surface 62a.

(18) The inspection system 70 of any one of Items (1) to (17), wherein the peripheral processor 60 is an exposer configured to irradiate exposure light onto the front surface Wa of the wafer W that faces the facing surface 62a.

In this case, in an exposure apparatus, the position of the facing surface 62a tends to significantly affect the processing result. Therefore, when the peripheral processor 60 is the exposer, it is more beneficial to be able to detect the position of the facing surface 62a with high accuracy.

(19) An inspection method of inspecting a wafer processing system 1 including a holder 51 configured to hold a wafer W, and a peripheral processor 60, which has a facing surface 62a facing a peripheral portion We of a front surface Wa of the wafer W held by the holder 51 and performs a process on the peripheral portion We, includes: holding, by the holder 51, a support plate 72 constituting an inspection substrate 71 in place of the wafer W; capturing images of surroundings of the support plate 72 by a capturer 73 provided on the support plate 72; storing a positional relationship between the facing surface 62a and an imaging target 63 provided on the peripheral processor 60 such that the imaging target 63 falls within a field of view of the capturer 73; acquiring an image I including the imaging target 63 by the capturer 73; and detecting a position of the facing surface 62a based on a position of the imaging target 63 in the image I and the positional relationship.

According to the above-described inspection method, the same effects as those of Item (1) can be obtained.

(20) A non-transitory computer-readable storage medium stores a program that causes an apparatus to execute the inspection method of Item (19).

According to the above-described storage medium, the same effects as those of Item (1) can be obtained.

According to the present disclosure, it is possible to provide an inspection system, an inspection method, and a non-transitory computer-readable storage medium that are effective in improving stability of process on a peripheral portion in a substrate processing apparatus.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An inspection system for inspecting a substrate processing apparatus including a holder configured to hold a substrate, and a peripheral processor, which has a facing surface facing a peripheral portion of a front surface of the substrate held by the holder and performs a process on the peripheral portion, the inspection system comprising:
an inspection substrate including a support plate held by the holder in place of the substrate, and a capturer provided on the support plate to capture images of surroundings of the support plate;
a storage configured to store a positional relationship between the facing surface and an imaging target provided on the peripheral processor such that the imaging target falls within a field of view of the capturer;
an acquirer configured to acquire an image including the imaging target from the capturer; and
a position detector configured to detect a position of the facing surface based on a position of the imaging target in the image and the positional relationship.

2. The inspection system of claim 1, wherein the substrate processing apparatus further includes a rotation driver configured to rotate the holder,
the inspection system further comprising: a rotation controller configured to direct the capturer toward the imaging target by the rotation driver,
wherein the acquirer acquires the image from the capturer directed toward the imaging target by the rotation controller.

3. The inspection system of claim 2, wherein the imaging target has a mark for positioning,
wherein the rotation controller further controls the rotation driver based on the image such that the mark falls within a predetermined range in the image, and
wherein the position detector detects the position of the facing surface based on the position of the imaging target in the image acquired in a state in which the mark falls within the predetermined range, and the positional relationship.

4. The inspection system of claim 3, wherein the mark is located between a first end and a second end of the imaging target, and
wherein the rotation controller is configured to move the mark into the predetermined range by:
rotating the holder in a direction in which the capturer is displaced from the first end toward the second end when the mark is outside the image and the first end is within the image; and
rotating the holder in a direction in which the capturer is displaced from the second end toward the first end when the mark is outside the image and the second end is within the image.

5. The inspection system of claim 2, wherein the substrate processing apparatus further includes a linear driver configured to move the holder toward the peripheral processor along a displacement direction perpendicular to a rotation axis of the holder, and
wherein the inspection substrate further includes an acceleration sensor provided on the support plate,
the inspection system further comprising: an imaging direction detector configured to detect an inclination of a field-of-view direction of the capturer with respect to the displacement direction based on a detection result of the acceleration sensor,
wherein the rotation controller directs the capturer toward the imaging target by the rotation driver based on a detection result of the inclination.

6. The inspection system of claim 5, further comprising:
an abnormality detector configured to detect an abnormality when the imaging target is not included in the image after the rotation controller rotates the holder by the rotation driver to direct the capturer toward the imaging target based on the detection result of the inclination.

7. The inspection system of claim 5, wherein the imaging direction detector is provided on the inspection substrate.

8. The inspection system of claim 1, wherein the substrate processing apparatus further includes a linear driver configured to move the holder toward the peripheral processor along a displacement direction perpendicular to a rotation axis of the holder,
the inspection system further comprising: a linear controller configured to adjust a position of the capturer by the linear driver such that the imaging target falls within a depth of focus of the capturer,
wherein the acquirer acquires the image from the capturer in a state in which the imaging target falls within the depth of focus.

9. The inspection system of claim 1, wherein the position detector detects the position of the facing surface further based on a relationship between a size of the imaging target in the image and an actual size of the imaging target.

10. The inspection system of claim 1, wherein the position detector detects the position of the facing surface further based on a relationship between a width of the imaging target in the image and an actual width of the imaging target in a direction perpendicular to the facing surface.

11. The inspection system of claim 1, wherein the position detector detects, as the position of the facing surface, a distance between the facing surface and a plane on which the front surface of the substrate held by the holder is positioned.

12. The inspection system of claim 11, wherein the position detector detects a distance between the facing surface and the plane based on the position of the imaging target in the image, the positional relationship, a relationship between a size of the imaging target in the image and an actual size of the imaging target, a position of the capturer with respect to the holder, and a thickness of the substrate.

13. The inspection system of claim 12, further comprising:
a warpage amount storage configured to store a warpage amount of the substrate in a state in which the substrate is held by the holder,
wherein the position detector detects the distance between the facing surface and the plane further based on the warpage amount.

14. The inspection system of claim 13, wherein the warpage amount storage stores a plurality of warpage amounts respectively corresponding to a plurality of sizes of the holder, and
wherein the position detector detects the distance between the facing surface and the plane further based on a warpage amount corresponding to the actual size of the holder among the plurality of warpage amounts.

15. The inspection system of claim 13, wherein the warpage amount storage is provided on the inspection substrate.

16. The inspection system of claim 11, further comprising:
an abnormality detector configured to detect an abnormality when the distance between the facing surface and the plane is outside a predetermined range.

17. The inspection system of claim 1, wherein the holder is configured to hold the substrate or the support plate by suction,
the inspection system further comprising: a suction controller configured to release the suction of the support plate suctioned by the holder, and cause the holder to re-suction the support plate, and
wherein the position detector detects the position of the facing surface based on an image acquired after the holder re-suctions the support plate.

18. The inspection system of claim 1, wherein the peripheral processor is an exposer configured to irradiate exposure light onto the front surface of the substrate that faces the facing surface.

19. An inspection method of inspecting a substrate processing apparatus including a holder configured to hold a substrate, and a peripheral processor, which has a facing surface facing a peripheral portion of a front surface of the substrate held by the holder and performs a process on the peripheral portion, the inspection method comprising:
holding, by the holder, a support plate constituting an inspection substrate in place of the substrate;
capturing images of surroundings of the support plate by a capturer provided on the support plate;
storing a positional relationship between the facing surface and an imaging target provided on the peripheral processor such that the imaging target falls within a field of view of the capturer;
acquiring an image including the imaging target by the capturer; and
detecting a position of the facing surface based on a position of the imaging target in the image and the positional relationship.

20. A non-transitory computer-readable storage medium storing a program that causes an apparatus to execute the inspection method of claim 19.
